(19) United States
(12) Patent Application Publication
(10) Pub. No.: US 2020/0039145 A1
(43) Pub. Date: Feb. 6, 2020

(54) Powder-Bed-Based Additive Manufacture of a Workpiece

(71) Applicant: Siemens Aktiengesellschaft, München (DE)

(72) Inventors: Darya Kastsian, Falkensee (DE); Daniel Reznik, Berlin (DE)

(73) Assignee: Siemens Aktiengesellschaft, München (DE)

(21) Appl. No.: 16/603,458

(22) PCT Filed: Apr. 13, 2017
(86) PCT No.: PCT/EP2017/058997

§ 371 Date: Oct. 7, 2019

(51) Int. Cl. B29C 64/153; B29C 64/264; B29C 64/393

(52) U.S. Cl. CPC B29C 64/153; B33Y 10/00; B29C 64/393; B29C 64/264

(57) ABSTRACT

Various embodiments include methods for the powder-bed-based additive manufacturing of a workpiece comprising: manufacturing the workpiece layer by layer in a powder bed, including solidifying a respective uppermost layer of the powder bed using an energy beam. During the solidification of the respective uppermost layer of the powder bed, analyzing a geometry of previously solidified layers below the respective uppermost layer. The method may include reducing an average power over time introduced by the energy beam per unit of area of the powder bed with application of correction parameters if the heat dissipation into the previously solidified layers is reduced in dependence on the workpiece depth available below the energy beam.

### CROSS-REFERENCE TO RELATED APPLICATIONS

This application is a U.S. National Stage Application of International Application No. PCT/EP2017/058997 filed Apr. 13, 2017, which designates the United States of America, the contents of which are hereby incorporated by reference in their entirety.

### TECHNICAL FIELD

The present disclosure relates to additive manufacturing. Various embodiments may include methods for the powder-bed-based additive manufacturing of a workpiece, in which the workpiece is manufactured layer by layer in a powder bed, wherein the respective uppermost layer of the powder bed is solidified by an energy beam to manufacture the workpiece.

### BACKGROUND

A method for additive manufacturing of a workpiece in a powder bed is described in DE 10 2015 205 316. Accordingly, a workpiece is manufactured in a powder bed in that the powder is melted by a laser beam. This can be problematic in the case of certain materials, for example, nickel-based super alloys, because the high cooling speeds in the molten pool of the laser can result in tensions in the component and a formation of an undesired metallic microstructure. As a countermeasure, it is proposed that the powder bed be preheated by means of a heating unit, so that the temperature difference of the powder and the already produced component is less in comparison to the molten pool and the cooling speed can thus also be reduced.

According to US 2016/0332379 A1, it is proposed that, for example, in the case of laser sintering, the amount of energy introduced by the laser can be adapted by the duration of a preceding solidification step of the preceding layer being taken into consideration at least in a subregion of the layer to be manufactured in order to determine the introduction of energy into the present layer. In this case, a correction factor is ascertained, which considers how high the introduction of energy was in preceding layers of the already manufactured component. Undesired component warping is to be counteracted thereby.

A further option according to WO 2016/049621 A1 is that preheating of the present layer to be solidified can be effectuated by an external energy source. In this case, a required heat profile of the layer to be solidified is computed, wherein subsequent layers still to be manufactured can also be taken into consideration in this case.

Powder-bed-based additive manufacturing methods in the context of this disclosure include methods in which the material from which a workpiece is to be manufactured is added to the workpiece layer by layer during the formation. In this case, the workpiece is formed already in its final formation or at least approximately in this formation by solidifying the contours defining the workpiece in the powder bed. To be able to manufacture the workpiece, data describing the workpiece (CAD model) are produced for the selected additive manufacturing method. The data are converted into data of the workpiece adapted to the manufacturing method to produce instructions for the manufacturing facility, so that the suitable process steps for successive manufacturing of the workpiece can run in the manufacturing facility. The data are produced for this purpose so that the geometrical data for the contour of the respective layers (slices) to be manufactured of the workpiece are available, which is also referred to as slicing.

Selective laser melting (SLM) and electron beam melting (EBM) are examples of additive manufacturing. These methods are suitable in particular for processing metallic materials in the form of powders, using which construction components can be manufactured. The starting point for carrying out an additive manufacturing method is a description of the workpiece in a geometry data set, for example, as an STL file (STL stands for standard tessellation language). The STL file contains the three-dimensional data for a preparation for the purpose of manufacturing by the additive manufacturing method. A manufacturing data set, for example, a CLI file (CLI stands for common layer interface) is generated from the STL file, which contains a preparation of the geometry of the workpiece suitable for additive manufacturing in slices describing the contour. The transformation of the data is referred to as slicing.

The result of the slicing is that the layers of the workpiece to be manufactured are equipped with a defined z height, for example, 50 μm. This means that in the case of a workpiece which is 100 mm tall, for example, 2000 workpiece layers have to be defined. Each of these workpiece layers also contains, in addition to its height in the z direction, an item of contour information in an x-y plane, which consists of one or more closed polygonal chains, in the interior of which the material of the workpiece layer is located, while no workpiece material is provided outside, i.e., the layer of the powder bed remains untreated.

In addition, the machine requires further specifications for manufacturing, for example, the height of the layers to be manufactured, the alignment of the writing vectors, i.e., the direction and length of the path which the energy beam describes on the surface of the powder bed, and the division of the workpiece layer to be produced into sectors, in which specific method parameters apply. Furthermore, focus diameter and power of the energy beam used are to be established. The CLI file and the manufacturing data together form a sequence plan, according to which the workpiece described in the STL file can be additively manufactured layer by layer in the manufacturing facility.

The foundation of the production of the sequence plan are the individual workpiece layers having the stored items of contour information thereof, on the basis of which an exposure strategy is established during the work preparation. This essentially consists of steps of contour exposure and hatching exposure. In the scope of the contour exposure, the energy beam tracks the contour line of the workpiece layer once or multiple times. In the scope of the hatching exposure (hatch), the area of the workpiece layer is typically filled up using exposure vectors guided in parallel in groups, wherein the groups typically form a rectangular pattern of individual segments.

During the execution of the above-described sequence plans in an additive manufacturing method, manufacturing problems are repeatedly observed, which can result in process aborts in the worst case. In particular in the case of components in which filigree structures having a small component volume are to be manufactured, overheating repeatedly occurs—linked with an enlargement of the molten pool, so that too many powder particles are melted. The formation of a molten bead may then be observed in the method sequence, which protrudes out of the powder bed after it solidifies and obstructs or even makes impossible the production of subsequent powder layers, since the powder sliders used for manufacturing the powder layer remain stuck at the solidified bead, which results in a process abort.

### SUMMARY

Some embodiments of the teachings herein include a method for the powder-bed-based additive manufacturing of a workpiece (19), in which the workpiece (19) is manufactured layer by layer in a powder bed (13), wherein the respective uppermost layer (25) of the powder bed (13) is solidified by an energy beam to manufacture the workpiece, characterized in that during the solidification of the uppermost layer (25) of the powder bed (13), the geometry located below the uppermost layer (25) of the already manufactured workpiece is taken into consideration, wherein the average power over time introduced by the energy beam (17) per unit of area of the powder bed is reduced with application of correction parameters if the heat dissipation into the already manufactured workpiece (19) is reduced in dependence on the workpiece depth (z) available below the energy beam.

In some embodiments, the average power over time introduced per unit of area of the powder bed is reduced by applying the following correction parameters:
the power of the energy beam (17) is reduced and/or
a feed rate of the energy beam (17) on the powder bed (13) is increased and/or
an irradiation pause is maintained between traveling along one exposure vector (36) and traveling along an adjacent exposure vector (36), wherein the exposure vectors each describe parts of the path which the energy beam (17) travels along to solidify the powder bed (13).

In some embodiments, the workpiece depth (z) available below the energy beam is computed from a data set describing the geometry of the workpiece (19).

In some embodiments, the workpiece depth (z) available below the energy beam is only taken into consideration up to an established maximum depth (zₘ).

In some embodiments, the maximum depth (zₘ) to be taken into consideration is established as at least 0.5 mm and at most 2 mm, e.g. 1 mm.

In some embodiments, the maximum depth (zₘ) to be taken into consideration is established as at least 10 and at most 40 layers, e.g. 20 layers.

In some embodiments, the respective workpiece depth (z) available below the energy beam for the uppermost layer (25) is described as a contour function (gcf) in dependence on the location for the area component to be solidified of the uppermost layer (25).

In some embodiments, the contour function (gcf) is scaled to 1, wherein the value 1 is reached where the maximum depth (zₘ) to be taken into consideration is reached.

In some embodiments, a correction function (vf), in which the correction parameters for the average power over time introduced by the energy beam (17) per unit of area of the powder bed are stored in dependence on the location, is associated with the contour function (gcf).

In some embodiments, the correction parameters of the correction function (vf) to be associated are determined in dependence on the average value of the correction function (vf) or the minimum value of the correction function (vf) along an exposure vector, wherein the exposure vector is a linear element of the feed of the energy beam.

In some embodiments, in the case of the determination of the correction parameters within a boundary zone (33) of the contour, a distance from the boundary of the contour is additionally taken into consideration.

In some embodiments, the respective workpiece depth (z) available below an energy beam (17) to be used for manufacturing is computed for layers (25) to be processed of the powder bed as a contour function (gcf) in dependence on the location for the area component of the layer (25) to be solidified.

In some embodiments, the dimension for the reduction of the average power over time introduced by the energy beam (17) per unit of area of the powder bed is determined by producing a test specimen (28), the correction parameters are derived from the dimension, and the correction parameters are stored with boundary conditions, which apply to the correction, for the manufacturing.

In some embodiments, the dimension for the reduction of the average power over time introduced by the energy beam (17) per unit of area of the powder bed is computed using a simulation program, the correction parameters are derived from the dimension, and the correction parameters are stored with boundary conditions, which apply to the correction, for the manufacturing.

As another example, some embodiments include a computer program product for producing a contour function (gcf) for use in a method as described above, characterized in that a production program module (CON) is provided, using which the respective workpiece depth (z) available below an energy beam (17) to be used for the manufacturing can be computed for a layer (25) to be manufactured as a contour function (gcf) in dependence on the location for the area component to be solidified of a layer (25) of the powder bed, the production program module (CON) comprises a first interface (S1) for inputting a data set describing the geometry of a workpiece (19) to be manufactured, and the production program module (CON) comprises a second interface (S4) for outputting said contour function (gcf).

In some embodiments, a simulation program module (SIM) is provided, using which the dimension for the reduction of the average power over time introduced by the energy beam (17) per unit of area can be computed, the simulation program module (SIM) comprises a third interface (S3) for inputting a data set describing the geometry of a simulated workpiece (19) to be manufactured, and the simulation program module (SIM) comprises a fourth interface (S4) for outputting said dimension.

### BRIEF DESCRIPTION OF THE DRAWINGS

Further details of the teachings herein are described hereafter on the basis of the drawings. Identical or corresponding drawing elements are each provided with identical reference signs and are only explained multiple times insofar as differences result between the individual figures. In the figures:

FIG. 1 shows an arrangement for executing an exemplary embodiment of a method incorporating the teachings herein having a schematic illustration in section of a laser melting facility and exemplary embodiments of the computer program products incorporating the teachings herein as a block diagram,

FIG. 2 shows a three-dimensional view of an exemplary embodiment of the method incorporating the teachings herein for ascertaining correction parameters by a test method,

FIG. 3 shows a schematic illustration of the contour function incorporating the teachings herein as a top view,

FIG. 4 schematically shows a three-dimensional view of an exemplary embodiment of the ascertainment of correction factors in dependence on exposure vectors according to one exemplary embodiment of the method incorporating the teachings herein, and

FIG. 5 shows an exemplary embodiment of the method incorporating the teachings herein as a flow chart.

### DETAILED DESCRIPTION

The teachings of the present disclosure describe methods for the powder-bed-based additive manufacturing of a workpiece, using which the probability of overheating of the molten pool is comparatively low. In addition, some of the example methods produce a contour function, which can be used in the above-mentioned method. Furthermore, some examples include methods for producing correction parameters, which can be used in the above-mentioned method for manufacturing a component. Some embodiments include computer program products, which enable the production of a contour function or the production of correction parameters, respectively, in accordance with the methods mentioned above in this regard.

Some embodiments of powder-bed-based additive manufacturing include, during the solidification of the uppermost layer of the powder bed, the geometry located below the uppermost layer of the already manufactured workpiece is taken into consideration. In some embodiments, this consideration has the effect that the average power over time introduced by the energy beam per unit of area of the powder bed is reduced with application of correction parameters if the heat dissipation into the already manufactured workpiece is reduced in dependence on the workpiece depth available below the energy beam. In this case, the available workpiece depth represents the workpiece volume available at this point, on which the heat dissipation from the molten pool is directly dependent. The larger the workpiece volume, the more heat can be absorbed and discharged from the molten pool. With a smaller workpiece volume, the heat dissipation is obstructed, since the powder bed which encloses this workpiece volume has a substantially lower heat conductivity and also a lower heat capacity.

The correction parameters may have the effect that the introduction of energy by the energy beam is reduced in critical zones of the workpiece layer to be manufactured. The introduction of energy may be described by the average power over time introduced per unit of area of the powder bed. Options which exist for defining correction parameters result therefrom. These options can be selected individually or in combination to influence the introduction of energy.

A first option is to reduce the power of the energy beam. Independent of the exposure strategy, the energy density introduced into the component is proportionally decreased in this way. Another option is to increase the feed rate of the energy beam on the powder bed. The power introduced per unit of area of the powder bed is decreased in this way, since the energy beam passes over a specific unit of area of the powder bed in a shorter time. A further option is to maintain an irradiation pause between traveling along the exposure vector and traveling along an adjacent exposure vector. The exposure vectors each define parts of the path which the energy beam travels along to solidify the powder bed, so that the pause between traveling along adjacent exposure vectors has the result that the power is reduced on average over time.

In some embodiments, the workpiece depth available below the energy beam is computed from a data set describing the geometry of the workpiece. These data are provided in any case because of the required work preparation for the additive manufacturing of the workpiece. It is possible to use the geometry data set (for example, embodied as an STL file) or the manufacturing data set (for example, embodied as a CLI file) as the data set describing the geometry of the workpiece.

In some embodiments, the workpiece depth available below the energy beam can only be taken into consideration up to an established maximum depth. This is because it has been shown that the critical states of overheating of the melt bath and the bead formation linked thereto only occur if the heat dissipation into the already manufactured component is significantly obstructed. However, it is unimportant from a determined workpiece depth how much component volume is additionally available below this determined workpiece depth, since the workpiece volume up to this depth is sufficient to ensure a sufficient heat dissipation. Therefore, the workpiece regions, which do not substantially participate in the heat dissipation, below this maximum depth remain unconsidered in the computation.

The maximum depth to be taken into consideration can be established as at least 0.5 mm and at most 2 mm, e.g. 1 mm. In some embodiments, it is possible to specify the maximum depth to be taken into consideration in already manufactured workpiece layers, since they have a defined thickness as a result of the production of the sequence plan. The maximum depth to be taken into consideration can accordingly be established as at least 10 and at most 40 layers, e.g. 20 layers.

The maximum depth to be taken into consideration is specifically dependent on the boundary conditions of the selected additive manufacturing method and the material to be processed. In the material to be processed, for example, the heat capacity and the heat conductivity play an essential role. Furthermore, the method parameters, in particular the standard provided introduction of energy, i.e., the average power over time introduced by the energy beam per unit of area of the powder bed, are an essential influencing factor.

In some embodiments, the procedure can be used that the respective workpiece depth available below the energy beam for the respective uppermost layer (i.e., for every layer, since every layer represents the uppermost layer once in the process, while it is presently being manufactured) is described as a contour function in dependence on the location for the area component to be solidified of the uppermost layer. The area component to be solidified of the uppermost layer of the powder bed is thus the area component which defines the workpiece layer and is located within the contour which is described by the contour function. The area component is thus describable in dependence on the location in an x-y coordinate system. The contour function can advantageously be stored in this case in tabular form from a grid of support points (x; y). A modified CLI file can be produced in this way, for example.

In some embodiments, the contour function is scaled to 1, wherein the value 1 is reached where the maximum depth to be taken into consideration is reached. In this way, a correction value of the contour function may be taken into consideration easily, for example, in dependence on support points, by the value of the contour function being used as the correction factor. If the noncritical maximum depth to be taken into consideration is reached in the already manufactured workpiece, this factor is thus at 1, i.e., no correction of the introduced energy of the energy beam is necessary. If the correction value reaches 0, this means that the workpiece has not yet been manufactured in the layer located underneath at this point. However, the energy introduced by the energy beam cannot be set to 0 here, but rather to a minimum value which is necessary to form a new workpiece layer not supported by previously produced workpiece layers.

In some embodiments, a correction function, in which the correction parameters for the average power over time introduced by the energy beam per unit of area of the powder bed are stored in dependence on the location, is associated with the contour function. The correction function can also be stored in tabular form for a grid of support points (x; y). This enables the consideration of experiential values for how the energy introduced by the energy beam has to be reduced in dependence on the already manufactured workpiece volume. If sufficient experiential knowledge is provided, the correction function can be supplied from a library, which provides possible correction parameters. These correction parameters can be compiled, for example, for specific materials to be processed, for specific characteristic component geometries, or for specific additive manufacturing methods.

In some embodiments, the correction parameters of the correction function to be associated are determined in dependence on the average value of the correction function or the minimum value of the correction function along an exposure vector, wherein the exposure vector is a linear element of the feed of the energy beam. In this embodiment of the method, the exposure vector is thus treated as the smallest unit to be corrected. This vector can be corrected using the correction factor of the correction function individually or in groups with other exposure vectors, in particular extending in parallel, of a segment within the contour to be exposed.

If the average value of the correction function is used, a resulting correction is thus less than if the minimum value is used to determine the correction parameter. If the minimum value is used, in a certain sense the worst-case scenario for the relevant exposure vector is taken into consideration and the resulting correction is accordingly stronger. A decision as to which value is to be taken into consideration can be made, for example, in dependence on the surroundings of the component.

In some embodiments, in the case of the determination of the correction parameter within a boundary zone of the contour, a distance from the boundary of the contour can additionally be taken into consideration in particular. A reduction of the workpiece volume located below the molten pool typically has a more critical result in the boundary zone of the contour, because less component volume is available at the boundary in any case in a direction transverse in relation to the Z direction. The minimum value of the correction function along an exposure vector can be used here, for example, while the mean value is used outside the boundary zone.

In some embodiments, the method includes producing a contour function in that the respective workpiece depth available below an energy beam to be used for manufacturing is computed for layers to be processed of the powder bed as a contour function in dependence on the location for the area component of the layer to be solidified. The respective layer to be manufactured, for which the contour function is computed, is the uppermost layer during the manufacturing in the above-described manufacturing method. However, the contour functions of all layers to be manufactured can also already be computed beforehand, since the items of information required for this purpose are already available in the data sets described in the workpiece. The above-explained advantages in the method control may be achieved using the method, according to which overheating of the molten pool can be prevented.

In some embodiments, a method for producing correction parameters for a correction function, can be used in the above-described method for additive manufacturing. In some embodiments, the dimension for the reduction of the average power over time introduced by the energy beam per unit of area of the powder bed is determined by producing a test specimen. The correction parameters can be derived from the determined dimension and stored with boundary conditions, which apply to the correction, for the manufacturing. An iterative procedure for checking the correction parameters is possible for this purpose. The correction parameters can then be stored, for example, in a library. The values can then be retrieved if needed if comparable structures result in the component to be manufactured as in the test specimen or previously produced workpieces.

In some embodiments, the dimension for the reduction of the average power over time introduced by the energy beam per unit of area of the powder bed is computed using a simulation program, to derive the correction parameters from the dimension. These can also be stored with the boundary conditions, which apply to the correction, for the manufacturing. An iterative procedure for checking the ascertained correction parameters is also possible here, by running through the simulation program multiple times. The simulation program can be applied to the manufacturing of test specimens or to the manufacturing of construction components. It is also possible to combine the above-described method, comprising the manufacturing of a test specimen, with the method, comprising a simulation.

In some embodiments, a computer program product produces a contour function, which is suitable for use in the above-described additive manufacturing method. In some embodiments, a production program module is provided in the computer program product, using which the respective workpiece depth available below an energy beam to be used for the manufacturing can be computed for a layer to be processed as a contour function in dependence on the location for the area component to be solidified of this layer of the powder bed. The production program module comprises a first interface for inputting a data set describing the geometry of a workpiece to be manufactured. In addition, the production program module comprises a second interface module for outputting said contour function. The production program module can thus be supplied with the required data for producing the contour function and can subsequently output the computed contour function.

In some embodiments, a computer program product produces correction parameters for a correction function, wherein the contour function can be applied in the additive manufacturing method described at the outset. In some embodiments, a simulation program module is provided, using which the dimension for the reduction of the average power over time introduced by the energy beam per unit of area can be computed. The simulation program module comprises for this purpose a third interface for inputting a data set describing the geometry of a simulated workpiece to be manufactured, since this data set is required for the simulation computation. Moreover, the simulation program module comprises a fourth interface for outputting said dimension. Boundary conditions used during the simulation may then be stored for the simulated manufacturing as correction parameters in consideration of the dimension.

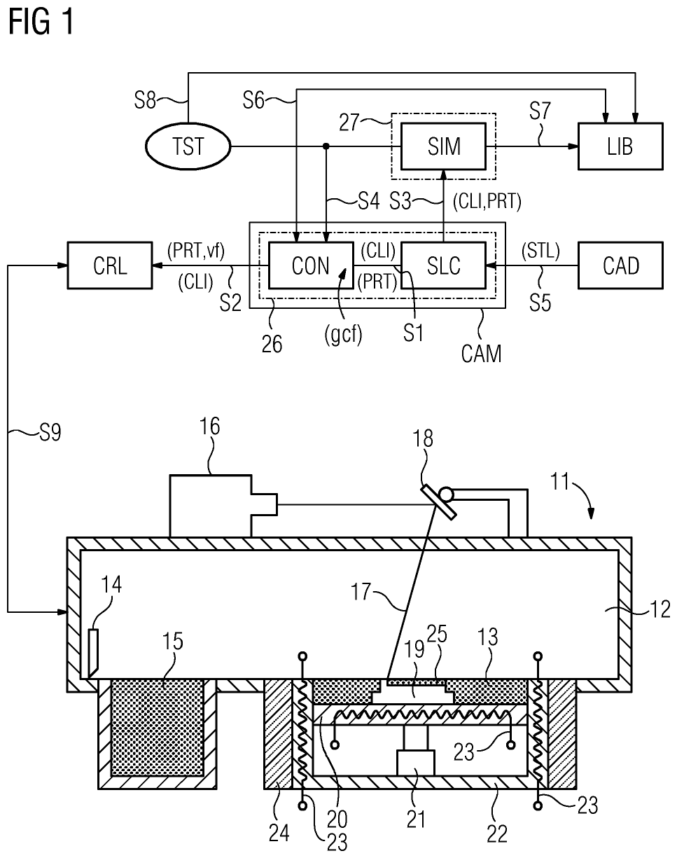

A facility 11 for laser melting is schematically shown in FIG. 1. It comprises a process chamber 12, in which a powder bed 13 can be manufactured. To manufacture in each case one layer of the powder bed 13, a distribution device in the form of a squeegee 14 is moved over a powder supply 15 and subsequently over the powder bed 13, whereby a thin layer of powder results in the powder bed 13, which forms an uppermost layer 25 of the powder bed. A laser 16 then generates a laser beam 17, which is moved by means of an optical deflection device having mirror 18 over the surface of the powder bed 13. In this case, the powder is melted at the point of incidence of the laser beam 17, whereby a workpiece 19 results.

The powder bed 13 results on a construction platform 20, which can be lowered via an actuator 21 in a cup-shaped housing 22 step-by-step by one powder layer thickness in each case. Heating devices 23 in the form of electrical resistance heaters (induction coils are alternatively also possible) are provided in the housing 22 and the construction platform 20, which can preheat the workpiece 19 in production and the particles of the powder bed 13. To limit the power consumption for preheating, an insulation 24 having low thermal conductivity is located externally on the housing 22.

The facility 11 for laser melting is controlled by a control unit CRL, which has to be supplied with suitable process data beforehand. To prepare the manufacturing of the workpiece 19, it is firstly necessary to generate the three-dimensional geometry data of the workpiece in a construction program CAD. The geometry data set STL thus generated is given via a fifth interface S5 to a system for manufacturing production CAM. On the system for manufacturing production CAM, on the one hand, a computer program product 26 is installed, which comprises a production program module CON and a transformation program module SLC. In the transformation program module, the construction data set STL (received via the first interface S1) is converted into a manufacturing data set CLI. Moreover, method parameters PRT are established by the transformation program module, which are relayed with the manufacturing data set CLI via the first interface S1 to the production program module CON. For this purpose, these are standardized manufacturing parameters.

The production program module CON is used to ascertain correction factors vf, which are to be taken into consideration in the manufacturing parameters PRT, so that overheating of the molten pool does not occur. These correction factors are relayed after the production thereof via an interface S2 to the control unit CRL for the facility 11 and supplemented if necessary by the control unit CRL with specific data of the facility 11. For this purpose, the control unit CRL also requires the manufacturing data set CLI, which contains the geometry of the machines distributed in workpiece layers. The control unit communicates via a ninth interface S9 with the facility.

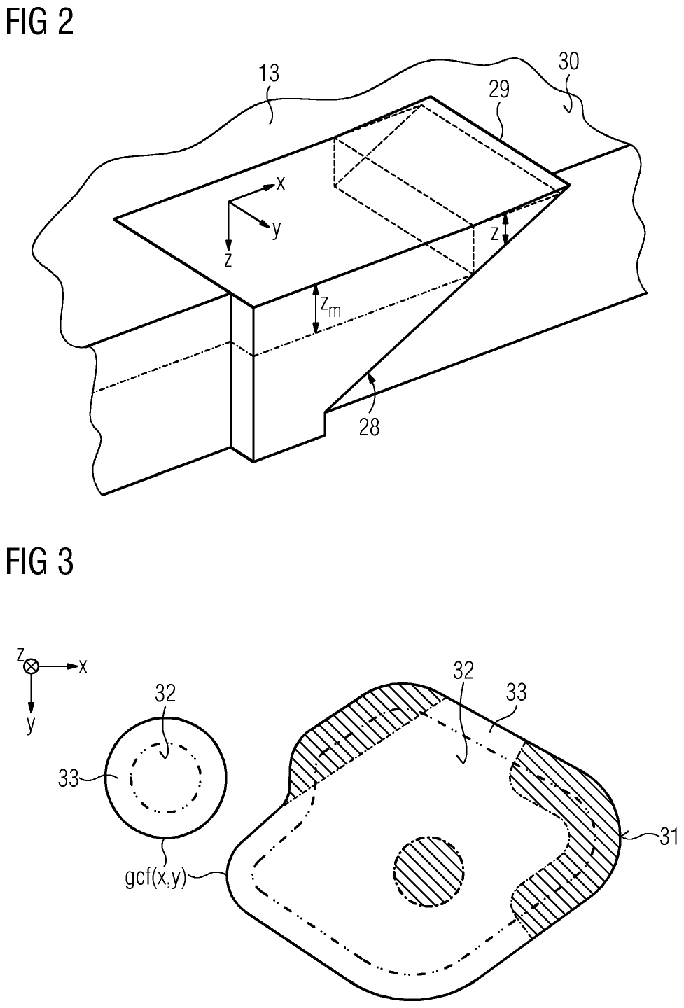

In order that correction parameters vf can be generated, the production program module CON firstly computes contour functions gcf, supplemented with items of depth information, of a workpiece to be manufactured, which, in addition to the information of the dimensions of the workpiece layer to be solidified, also contains an item of location-dependent information as to how large the workpiece depth z available under the energy beam is (cf. FIG. 2). This information is dependent on the variables x and y, which can be expressed by the expression gcf(x, y). The correction parameters vf, which are also dependent on the variables x and y, may then be ascertained in a location-resolved manner from the contour function, because of which vf can also be written as a function vf(x, y).

To compute the correction function vf, the production program module CON may use data which can originate from a library LIB. This is shown according to FIG. 1 as an external library LIB and is connected via a sixth interface to the production program module CON (communication possible in both directions).

To obtain data for the production of correction parameters vf, a simulation program module SIM can also be used, which is implemented in a second computer program product 27. It receives the manufacturing data set CLI and manufacturing parameters PRT via a third interface S3, wherein additive manufacturing of the workpiece can be simulated using these data. In some embodiments, typical partial structures of workpieces or test specimens can be computed using the simulation program. The result of these simulation computations can be stored in the library LIB via a seventh interface S7.

In some embodiments, test structures TST can be manufactured using the facility 11 or other facilities to ascertain whether overheating of the molten pool occurs. In this manner, correction parameters can also be tested out. These results can also be stored in the library LIB utilizing an eighth interface S8. Alternatively, the test results of the test TST or the simulation computations in the simulation program module SIM can also be relayed via a fourth interface S4 to the production program module CON, so that the correction parameters of can be ascertained therefrom.

FIG. 2 shows a possible structure of a test specimen 28, which is shown with a part of the powder bed 13 surrounding the test specimen 28. It has a wedge-shaped structure, wherein a boundary 29 results in the uppermost layer in this way, under which no material of the test specimen 28 is present in the powder bed 13. In this way, molten pool overheating occurs (not shown), which has the result that more material is solidified than is provided on the basis of the method sequence. The actual component geometry of the test specimen 28 manufactured up to this point therefore deviates from the target geometry, which may be indicated by the dashed boundary. Thus, more material is solidified, so that the boundary 29 protrudes out of the surface of the powder bed 13. The wedge-shaped region indicated by dashed lines is, because of a limited depth z of the component up to the transition to the powder bed 13, to be evaluated as critical with respect to possible overheating of the molten pool.

To manage this problem, the following contour function gcf(x, y) is computed of the test specimen 28 (and also of a workpiece 19, which is to be manufactured according to FIG. 1):

$$gcf ( x , y ) = \frac{1}{{z}_{m}} {\int }_{z - {z}_{m}}^{z} ρ ( x , y , z ) dz ;$$

$$ρ ( x , y , z ) = \{ \begin{matrix}1 , & ( x , y , z ) in the workpiece \\ 0 , & otherwise\end{matrix}$$

where
z=actual depth of the sample body 28 below a surface 30 of the powder bed
zₘ=the maximum depth of the sample body 28 to be taken into consideration.

The computer ascertainment can be carried out on the basis of the construction data set STL or on the basis of the manufacturing data set CLI. The values for the available component depth z are typically stored in tabular form for a specific number of support points (x; y) located in a grid and can be between 0 and 1 according to the above computation method. Therefore, a scaling of the contour function gcf is performed by the computation rule, wherein the maximum depth of the sample body 28 to be taken into consideration is set equal to 1.

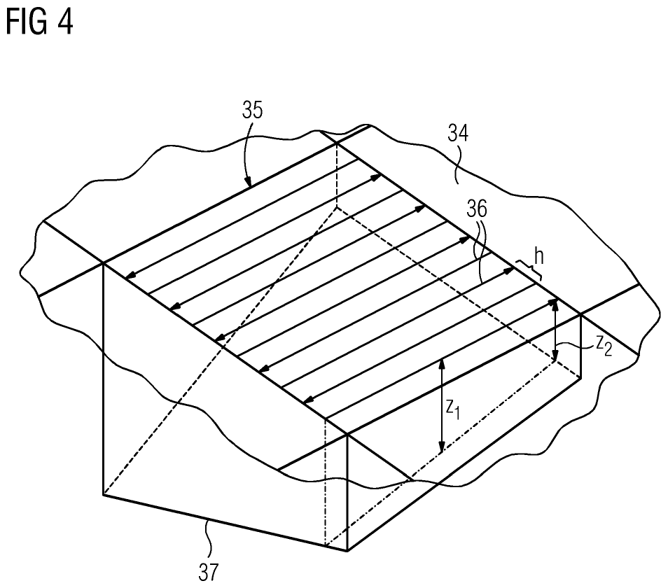

According to FIG. 3, a specific contour described by the contour function gcf(x, y) is shown, wherein it can also consist of multiple subregions. The regions in which z<zₘ are shown shaded in FIG. 3 and are delimited by a dot-dash line. These can be located on an outer contour 31 of the workpiece layer 32 to be manufactured or also its interior. Moreover, a boundary zone 33 of the workpiece layer to be manufactured is indicated by a dash-double-dot line in each case in FIG. 3, in which boundary conditions additionally applicable for the boundary zone can be taken into consideration when ascertaining correction factors.

According to FIG. 4, a detail 34 of the surface to be exposed of a workpiece is shown. A segment 35, which is to be exposed using a number of exposure vectors 36, is located in this detail. These vectors each have a specific length and extend in parallel to one another in the segment 35 at a specific distance (hatch) h. To determine the depth z of the workpiece located under an exposure vector 36, either the average value z₁ or the minimum value z₂ can be ascertained. This is stored for the relevant exposure vector 36 as a supporting value in the contour function gcf under the relevant coordinates (x; y). It is clear from FIG. 4 that these values z change for each of the exposure vectors 36, since the component volume located under the segment 35 is indicated by a wireframe model 37.

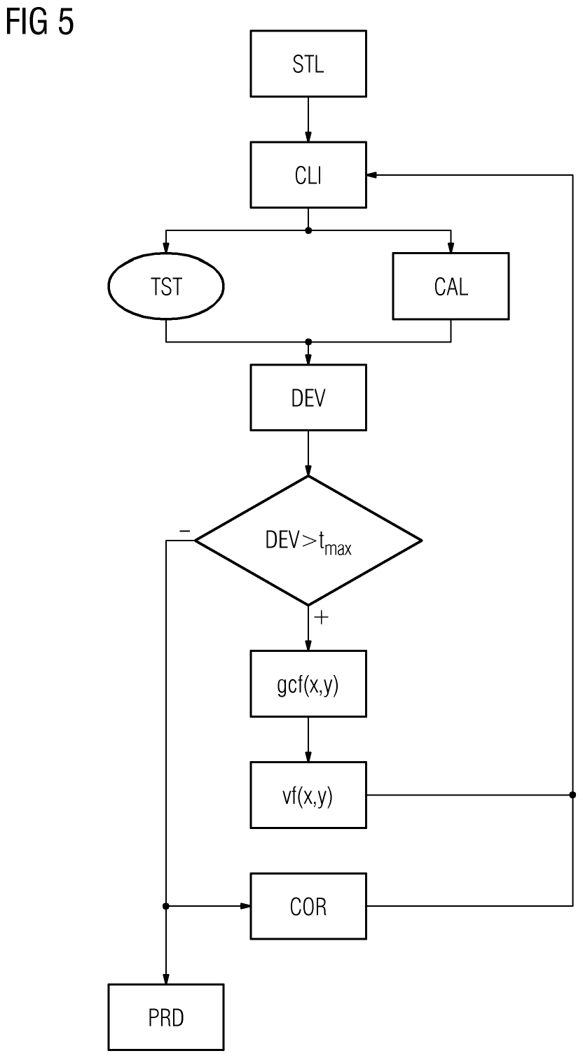

An example method incorporating teachings of the present disclosure for the additive manufacturing of a workpiece is shown as a flow chart of FIG. 5. As described for FIG. 1, the method begins with the production of a geometry data set STL for a workpiece to be manufactured. This data set is transformed in a manner known per se in a following step into a manufacturing data set CLI, which describes the workpiece to be manufactured in slices. This manufacturing data set CLI can be used to produce the workpiece using standardized manufacturing parameters, wherein a test TST can be carried out, in which the workpiece is manufactured in a facility for additive manufacturing. In some embodiments, the manufacturing can also be checked by a simulation computation CAL. In both cases, it may subsequently be established whether dimensional deviations DEV are to be established because of overheating of the molten pool. It is to be noted in this case that dimensional deviations can also have other reasons, so that in particular it is necessary to search in critical zones for dimensional deviations which permit molten pool overheating to be concluded. These critical zones are to be found, as already explained, where only a small workpiece volume is available below the energy beam during the manufacturing of the relevant layer.

If the dimensional deviations DEV are smaller than maximum permissible tolerances tₘₐₓ, a production PRD of the workpiece can be started. The data which are necessary for the manufacturing of this component can be stored as correction data and can be used to produce later manufacturing data sets CLI.

If the dimensional deviations DEV are supposed to be greater than the permissible tolerances tₘₐₓ, a modified contour function gcf(x, y) thus has to be produced, from which correction parameters of the correction function vf(x, y) can be ascertained in dependence on the depth information z of the workpiece manufactured up to this point. These are then taken into consideration in a further test TST or a further simulation computation CAL, wherein the dimensional deviations DEV are again determined. These iterations are repeated until the dimensional deviations DEV are less than the maximum permitted tolerances tₘₐₓ.

What is claimed is:

1. A method for the powder-bed-based additive manufacturing of a workpiece, the method comprising:
manufacturing the workpiece layer by layer in a powder bed, including solidifying a respective uppermost layer of the powder bed using an energy beam;
during the solidification of the respective uppermost layer of the powder bed, analyzing a geometry of previously solidified layers below the respective uppermost layer;
reducing an average power over time introduced by the energy beam per unit of area of the powder bed with application of correction parameters if the heat dissipation into the previously solidified layers is reduced in dependence on the workpiece depth available below the energy beam.

2. The method as claimed in claim 1, wherein the average power over time introduced per unit of area of the powder bed is reduced by applying one or more of the following correction parameters:
reducing a power of the energy beam;
increasing a feed rate of the energy beam on the powder bed; and
maintaining an irradiation pause between traveling along one exposure vector and traveling along an adjacent exposure vector, wherein the exposure vectors each describe parts of the path which the energy beam travels along to solidify the powder bed.

3. The method as claimed in claim 1, further comprising calculating the workpiece depth available below the energy beam using a data set describing the geometry of the workpiece.

4. The method as claimed in claim 1, wherein the workpiece depth available below the energy beam is only taken into consideration up to an established maximum depth.

5. The method as claimed in claim 4, wherein the maximum depth is at least 0.5 mm and at most 2 mm.

6. The method as claimed in claim 4, wherein the maximum depth corresponds to at least 10 and at most 40 layers.

7. The method as claimed in claim 1, further comprising describing the respective workpiece depth available below the energy beam for the uppermost layer as a contour function in dependence on a location for the area component to be solidified of the uppermost layer.

8. The method as claimed in claim 4, further comprising describing the respective workpiece depth available below the energy beam for the uppermost layer as a contour function in dependence on a location for the area component to be solidified of the uppermost layer;
wherein the contour function is scaled to 1;
wherein the value 1 is reached where the maximum depth is reached.

9. The method as claimed in claim 7, further comprising storing a correction function wherein the correction parameters for the average power over time introduced by the energy beam per unit of area of the powder bed based at least in part on the location, is associated with the contour function.

10. The method as claimed in claim 9, further comprising determining the correction parameters of the correction function based at least in part on the average value of the correction function or the minimum value of the correction function along an exposure vector;
wherein the exposure vector is a linear element of the feed of the energy beam.

11. The method as claimed in claim 1, further comprising accounting for, in the case of the determination of the correction parameters within a boundary zone of the contour, a distance from the boundary of the contour.

12. A method as claimed in claim 7, further comprising computing the respective workpiece depth available below an energy beam for layers to be processed of the powder bed as a contour function in dependence on the location for the area component of the layer to be solidified.

13. A method as claimed in claim 9, further comprising determining
the dimension for the reduction of the average power over time introduced by the energy beam per unit of area of the powder bed by producing a test specimen;
deriving the correction parameters from the dimension; and
storing the correction parameters with boundary conditions, which apply to the correction, for the manufacturing.

14. A method as claimed in claim 9, further comprising:
computing the dimension for the reduction of the average power over time introduced by the energy beam per unit of area of the powder bed using a simulation program;
deriving the correction parameters from the dimension; and
storing the correction parameters with boundary conditions, which apply to the correction, for the manufacturing.

15. A computer program product for describing a respective workpiece depth available below an energy beam for an uppermost layer as a contour function in dependence on a location for an area component to be solidified of the uppermost layer, the product including a set of instructions stored in a non-transitory medium and when executed by a processor, causing the processor to:
compute the respective workpiece depth available below the energy beam to be used for additive manufacturing for the layer to be manufactured as a contour function in dependence on the location for the area component to be solidified of a respective layer of a powder bed;
receive a data set describing a geometry of a workpiece to be manufactured; and
provide as output for said contour function.

16. (canceled)
